(19) United States
(12) Patent Application Publication
(10) Pub. No.: US 2016/0300963 A1
(43) Pub. Date: Oct. 13, 2016

(54) SOLAR CELL AND FABRICATION METHOD THEREOF

(71) Applicant: NEO SOLAR POWER CORP., Hsinchu (TW)

(72) Inventors: Chia-Pang Kuo, Kaohsiung City (TW); Shr-Han Feng, New Taipei City (TW); Chun-Min Lin, Taoyuan City (TW)

(21) Appl. No.: 14/987,671

(22) Filed: Jan. 4, 2016

(30) Foreign Application Priority Data
Apr. 9, 2015 (TW) 104111486

(51) Int. Cl. H01L 31/0216; H01L 31/0224; H01L 31/0232; H01L 31/0236

(52) U.S. Cl. CPC H01L 31/02168; H01L 31/02363; H01L 31/022441; H01L 31/02327

(57) ABSTRACT

A solar cell with high-reflectivity region and narrow etch mark is disclosed. The solar cell includes a semiconductor substrate having a first surface and a second surface, a low-reflectivity region in and on the semiconductor substrate, and an annular etch mark disposed on the first surface and surrounding the low-reflectivity region. The etch mark is located along the perimeter of the first surface and has an average width that is not greater than 2 mm. The second surface is a surface with high reflectivity.

### CROSS REFERENCE TO RELATED APPLICATION

This application claims priority from Taiwan Patent application Ser. No. 104111486, filed Apr. 9, 2015.

### BACKGROUND OF THE INVENTION

1. Field of the Invention

The present invention relates generally to the field of solar cell technology. More specifically, the present invention relates to a high-efficiency solar cell and a fabrication method thereof. The solar cell has a high-reflectivity region on the backside and a narrow etch mark on the front side.

2. Description of the Prior Art

A solar cell is an electrical device that converts the energy of light directly into electricity by the photovoltaic effect. The light incident into the semiconductor substrate of the solar cell generates electron-hole pairs at the PN junction. Before they are recombined, the electrons and holes are collected by the cell front electrode on light-receiving surface and rear electrode, respectively, thereby generating photocurrent. A portion of the incident light that passes through the semiconductor substrate may be reflected at the backside of the substrate, thereby enhancing optical trapping. It is known that the polished backside surface increases the backside reflection of the light incident into the front side of solar cell.

Typically, after the front side diffusion and the formation of the PN junction, the prior art fabrication method of a crystalline silicon solar cell includes etching the wafer backside and wafer edge by using chemical etchant to achieve the effects of edge isolation and backside polishing. When etching the backside of the wafer using the chemical etchant, a so-called “etch mark” is typically formed along the perimeter of the front side of the wafer.

Currently, wet etching of the wafer backside and wafer edge is usually carried out in an edge-isolation equipment called “InOxSide” by RENA Sondermaschinen GmbH (hereinafter RENA tool) or PSG removal and edge isolation tool by Gebr. Schmid GmbH & Co. (hereinafter Schmid tool). Schmid tool uses water film to cover the front side of the wafer and uses rollers at the backside to perform contact etching. The disadvantage includes incomplete etching of the edge (no obvious etch mark on the front side) resulting in poor isolation, low shunt resistance, and high leakage current. In a RENA tool, the wafer floats on an acidic chemistry whereby silicon etching happens only on the backside of the wafer. However, to achieve the effect of backside polishing, a higher etching rate is needed, resulting in serious etching at the front side and therefore a wide etch mark. The wide etch mark leads to a poor appearance and reduced battery performance.

Therefore, there is a need in this technical field to provide an improved method for fabricating the solar cell, which is capable of making a backside polished solar cell with high-reflectivity region and achieving excellent isolation effect and enhanced battery performance.

### SUMMARY OF THE INVENTION

It is one object of the invention to provide an improved solar cell structure having a high-reflectivity region on its backside and a low-reflectivity region and narrow etch mark on its front side, thereby enhancing the battery performance.

According to one aspect of the invention, a solar cell includes a semiconductor substrate having a first surface and a second surface. The first surface comprises a low-reflectivity region. The second surface comprises a high-reflectivity region. The second surface is a polished surface. An etch mark is disposed along perimeter of the first surface and surrounding the low-reflectivity region to thereby constitute an annular pattern. The etch mark has an average width that is not greater than 2 mm.

According to one embodiment of the invention, a solar cell is provided. When the high-reflectivity region and the low-reflectivity region are irradiated with light of the same wavelength, a reflectivity of the high-reflectivity region is greater than that of the low-reflectivity region.

According to another embodiment of the invention, a method for fabricating a solar cell is provided. A semiconductor substrate having a first surface and a second surface is prepared. The first surface comprises a low-reflectivity region. A wafer surface cleaning and texturing process is performed to form textured surface structures on the first surface and the second surface. A backside polish process is performed to polish away the textured surface structure on the second surface, thereby forming a high-reflectivity region on the second surface. After the backside polish process, a diffusion process is performed to form a phosphosilicate glass (PSG) layer and a doped layer on the semiconductor substrate. An isolation process is performed to remove the doped layer from the second surface and an edge of the semiconductor substrate, thereby forming an etch mark along perimeter of the first surface and surrounding the low-reflectivity region as an annular pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective top view showing the front side of an exemplary solar cell according to one embodiment of the invention.

FIG. 2 is a schematic, cross-sectional diagram taken along line I-I′ in FIG. 1.

FIG. 3 to FIG. 7 are schematic, cross-sectional diagrams showing an exemplary method for fabricating a solar cell according to one embodiment of the invention.

FIG. 8 shows a curve diagram of reflectivity of the high-reflectivity region versus light wavelength.

FIG. 9 shows a curve diagram of reflectivity of the low-reflectivity region versus light wavelength.

### DETAILED DESCRIPTION

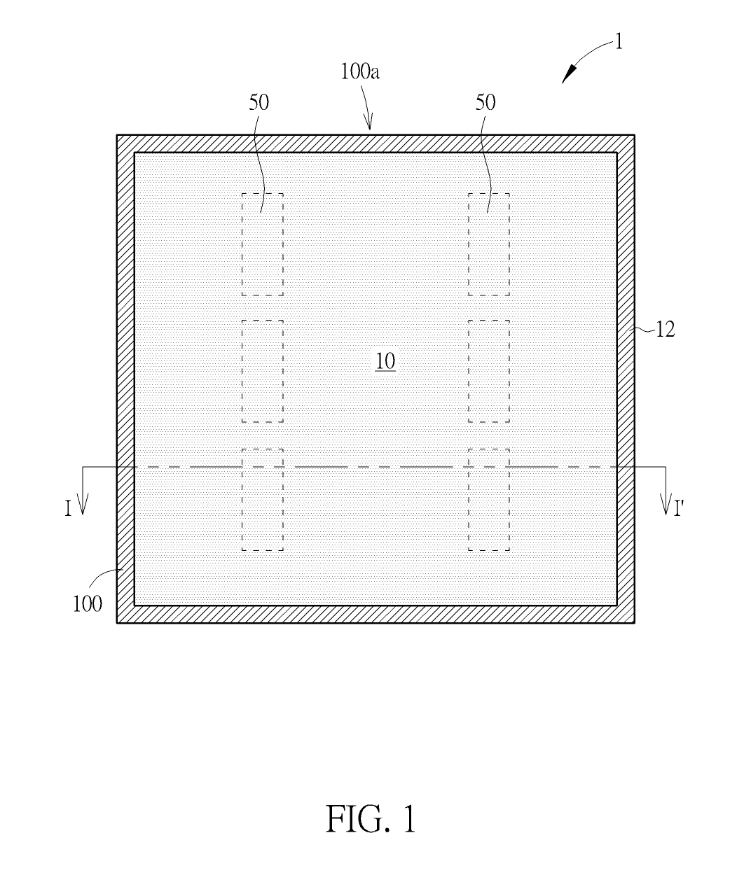

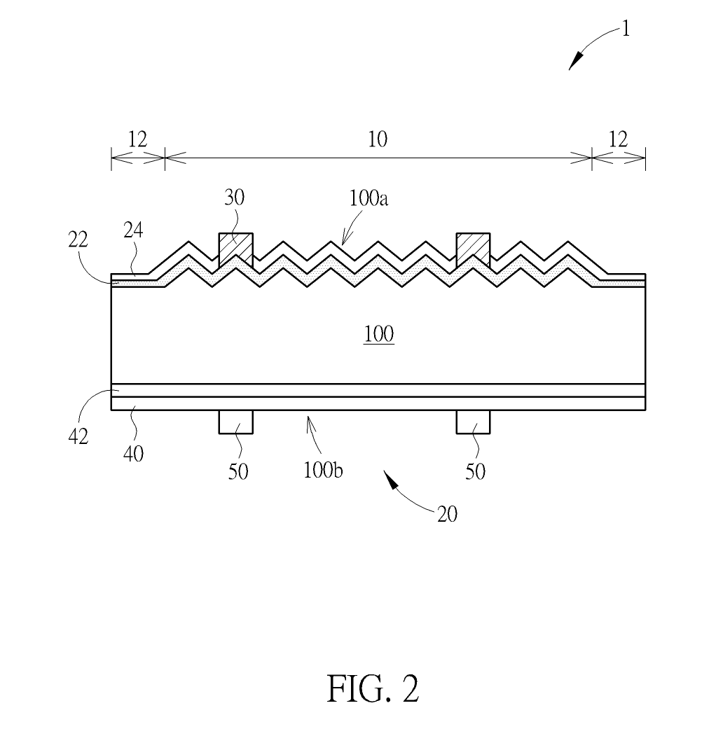

Please refer to FIG. 1 and FIG. 2. FIG. 1 is a perspective top view showing the front side of an exemplary solar cell according to one embodiment of the invention. FIG. 2 is a schematic, cross-sectional diagram taken along line I-I′ in FIG. 1.

As shown in FIG. 1 and FIG. 2, the solar cell 1 of the invention includes a semiconductor substrate 100 having a first surface 100a (also referred to as “front side” or “light-receiving surface”) and a second surface 100b (also referred to as “back side” or “reflection surface”). The first surface 100a and the second surface 100b are two opposite surfaces of the semiconductor substrate 100. According to the embodiment, the semiconductor substrate 100 may be an N-type or a P-type crystalline silicon substrate, but not limited thereto. The first surface 100a of the semiconductor substrate 100 includes a low-reflectivity region (textured surface) 10 and an etch mark 12. After polishing, a high-reflectivity region (polished surface) 20 is formed on the second surface 100b.

In accordance with the embodiment of the present invention, the etch mark 12 is located along the perimeter of the surface 100a and is an annular pattern that surrounds the low-reflectivity region 10. According to the embodiment, an average width of the etch mark 12 is not greater than 2 mm.

The aforesaid low-reflectivity region 10, etch mark 12, and high-reflectivity region 20 can be visually distinguished from the appearance. According to the embodiment, the color of the low-reflectivity region 10 is usually dark gray, the color of the etch mark 12 usually is usually burned black, while the color of the high-reflectivity region 20 is usually pale gray. When the first surface 100a and the second surface 100b are irradiated with light of the same wavelength, the amount of the reflected light at the first surface 100a is less than that of the second surface 100b because the second surface 100b has a high-reflectivity region and the first surface 100a has a low-reflectivity region 10.

As shown in FIG. 2, according to the embodiment of the present invention, the first surface 100a of the solar cell 1 may further include an N-type or P-type doped emitter layer 22 and at least one anti-reflective layer 24. The anti-reflection layer 24 may comprise silicon nitride, silicon oxide or silicon oxynitride, but is not limited thereto. In other embodiments, a multi-layer anti-reflection layer may be disposed on the first surface 100a of the solar cell 1, and each layer of the multi-layer antireflective layer is selected from the group comprised of silicon nitride, silicon oxide and silicon oxynitride.

In the embodiment, the solar cell 1 may further include at least one front side contact electrode 30 on the first surface 100a. For example, sliver paste may be screen printed on the first surface 100a and fired the paste the solar cell 1 to form the front side contact electrode 30 on the first surface 100a of the solar cell 1.

In the embodiment, the solar cell 1 may further include a back surface field (BSF) 42 and a backside contact electrode 40 on the second surface 100b. The backside contact electrode 40 includes aluminum, but not limited thereto. In the embodiment, pad electrodes 50 are provided on the backside contact electrode 40. For example, the pad electrode may be screen printed with solver paste and fired. The pad electrode 50 is indicated by dashed line. The pad electrode 50 may be two discontinuous stripes in parallel to each other, but not limited thereto. In other embodiments, the pad electrode 50 may have a continuous structure, a partially continuous structure or other variations.

A person ordinarily skilled in the art should appreciate that the crystalline silicon solar cell structure illustrated in FIG. 2 should not be used to limit the scope of the present invention. The semiconductor substrate of the present invention may be applied to other types of solar cell structure, e.g., Passivated Emitter Rear Cell (PERC) or Bifacial solar cell. When using the semiconductor substrate to form the PERC, preferably, the first surface 100a with the low-reflectivity region 10 is used as the light-receiving surface, and the second surface 100b with the high-reflectivity region 20 is used as the reflection surface. Further, a backside contact electrode 40 and Local BSF are formed on the second surface 100b.

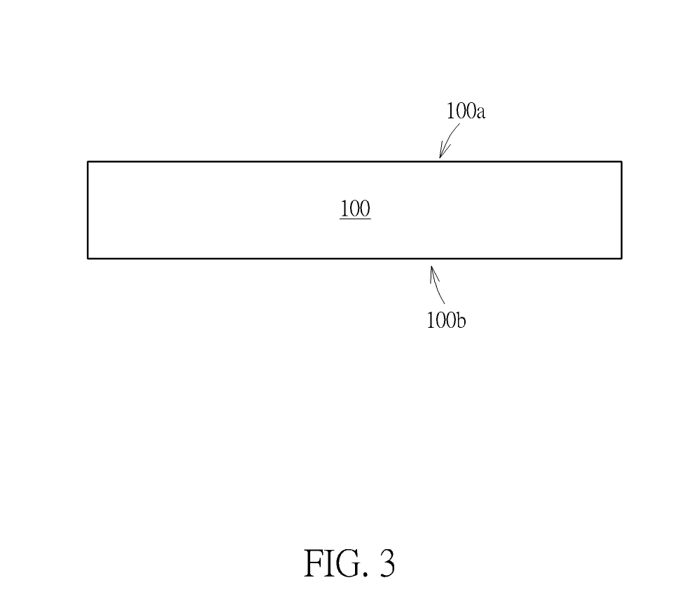

An exemplary method for fabricating a solar cell according to one embodiment of the invention will be described in greater detail below with reference to FIG. 3 to FIG. 7.

First, as shown in FIG. 3, a semiconductor substrate 100 is provided. The semiconductor substrate 100 has a first surface 100a (or light-receiving surface) and a second surface 100b (or reflection surface). According to the embodiment of the present invention, the semiconductor substrate 100 may be an N-type or a P-type crystalline silicon substrate.

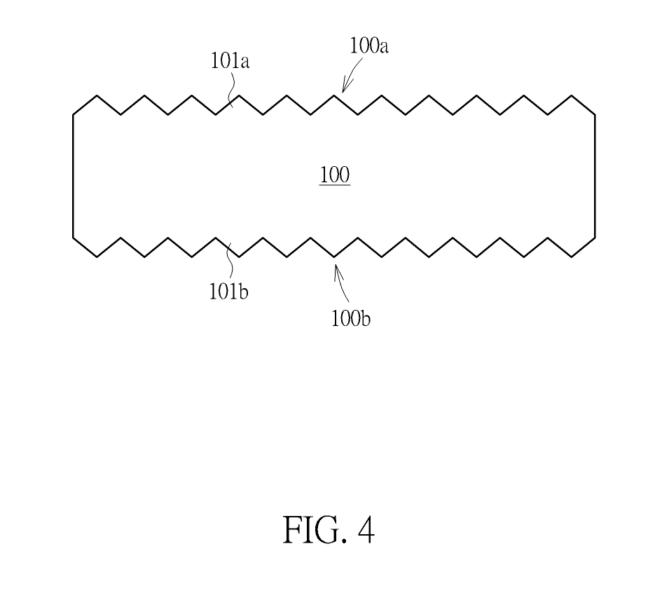

As shown in FIG. 4, a wafer surface cleaning and texturing process is performed to form textured surface structures 101a and 101b having pyramid-like protrusions. The first surface 100a and the second surface 100b of the semiconductor substrate 100 are both hydrophobic surfaces.

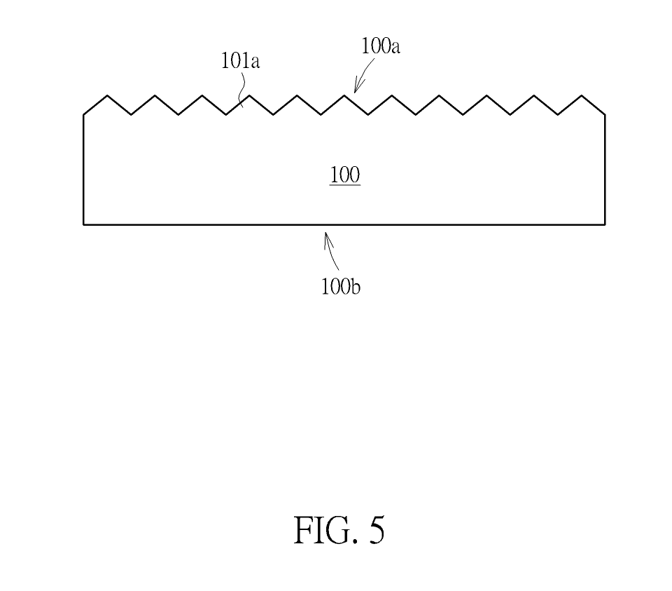

As shown in FIG. 5, a backside polish process is then carried out to polish the textured surface structure 101b on the second surface 100b, thereby forming a flat second surface 100b. According to the embodiment, the aforesaid backside polish process may include use a hydrophilic etchant to etch and polish the second surface 100b. For example, the semiconductor substrate 100 is horizontally placed on a plurality of rollers. The hydrophilic etchant is driven by the rollers, and then the hydrophilic etchant contacts the second surface 100b for a predetermined time period and a predetermined thickness of the second surface 100b will be etched.

According to the embodiment, the aforesaid hydrophilic etchant may include hydrofluoric acid (HF), nitric acid (HNO₃), and sulfuric acid (H₂SO₄). The aforesaid predetermined time period may range between 80 seconds and 360 seconds. According to the predetermined time period, the aforesaid predetermined thickness may range between 1.3 micrometers and 6 micrometers. According to the embodiment, the backside polish process does not form obvious etch mark on the first surface 100a of the semiconductor substrate 100.

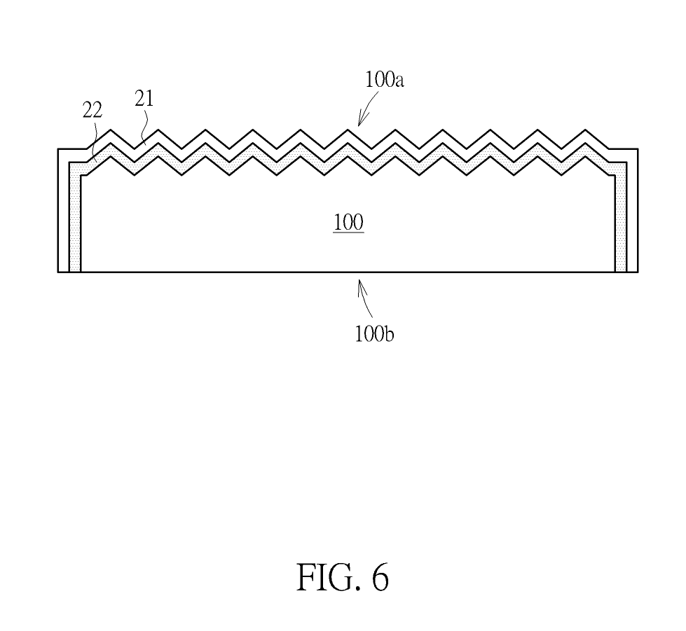

Subsequently, as shown in FIG. 6, a diffusion process is carried out to form at least a phosphosilicate glass (PSG) layer 21 and a doped emitter layer 22 on the first surface 100a of the semiconductor substrate 100. According to the embodiment, the doped emitter layer 22 is an N-type doped layer. At this point, the semiconductor substrate 100 is covered with the PSG layer 21 that is a hydrophilic surface.

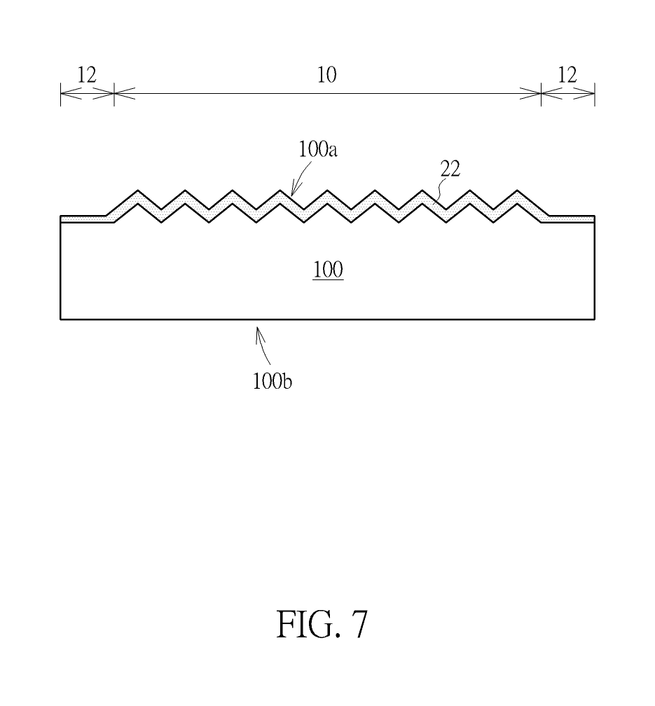

As shown in FIG. 7, an isolation process is then carried out to remove the doped layer from the second surface 100b and the edges of the semiconductor substrate 100, which is formed in the previous diffusion process. According to the embodiment, the isolation process may include using hydrophilic etchant to etch the second surface 100b and the edges of the semiconductor substrate 100. For example, the semiconductor substrate 100 maybe horizontally placed on a plurality of rollers. The hydrophilic etchant is driven by the rollers, and then the hydrophilic etchant contacts the second surface 100b for a predetermined time period and a predetermined thickness of the second surface 100b will be etched.

According to the embodiment, the aforesaid hydrophilic etchant may include hydrofluoric acid (HF), nitric acid (HNO₃), and sulfuric acid (H₂SO₄). According to the embodiment, during the isolation process, the semiconductor substrate 100 includes a hydrophilic surface, and an etch mark 12 will be formed on the first surface 100a of the semiconductor substrate 100 after the isolation process is complete. As previously described, the etch mark 12 is located along the perimeter of the first surface 100a to form an annular pattern, a closed-loop, that encloses the low-reflectivity region 10. According to the embodiment, the etch mark 12 has an average width that is not greater than 2 mm.

Optionally, after the isolation process, the semiconductor substrate 100 may be treated by an alkaline bath to neutralize the residual acid. For example, the semiconductor substrate 100 may be washed by using potassium hydroxide (KOH) solution. Thereafter, the semiconductor substrate 100 may be treated by an HF bath. The semiconductor substrate 100 that is already treated by alkaline bath is dipped in the HF solution in order to completely removing the PSG layer 21.

Subsequent fabrication process steps may include forming at least an anti-reflection layer on the doped emitter layer 22, then using metal paste to form the electrode patterns on the front and rear sides of the solar cell through screen printing method, followed by firing at high temperatures to form the contact electrodes, thereby forming the solar cell structure as depicted in FIG. 2. The details of the aforesaid subsequent fabrication process steps are known in the art and are therefore omitted for the sake of simplicity.

The solar cell fabricated according to the aforesaid fabrication process of the invention has high reflectivity (˜33% @600 nm) and a narrower (≦2 mm) etch mark on the front side of the solar cell. The increase of efficiency of the invention solar cell is up to 0.15˜0.17%, thereby achieving a high-efficiency (˜20.48%) solar cell.

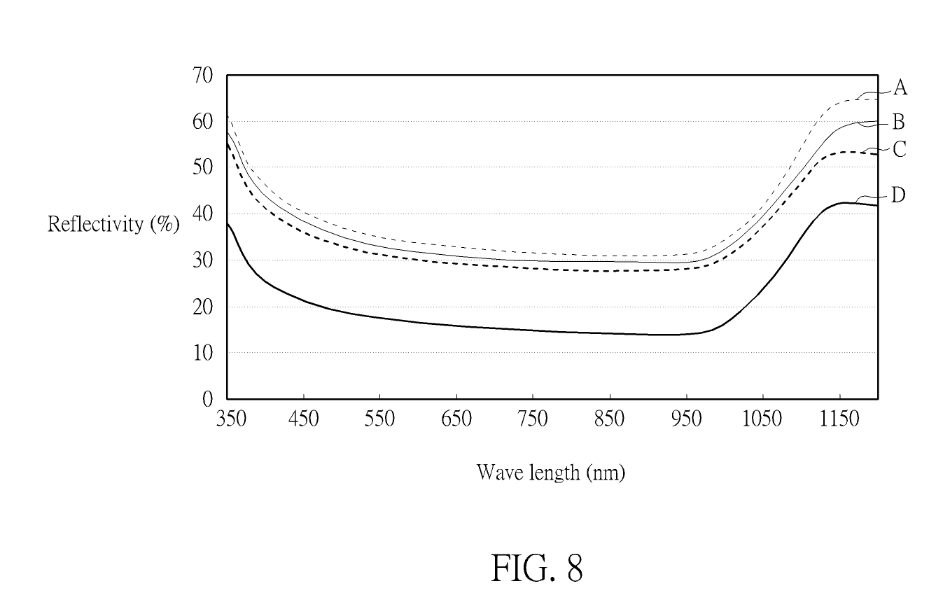

FIG. 8 shows a curve diagram of reflectivity of the high-reflectivity region versus light wavelength. In FIG. 8, curve A to curve C are measured by samples that are solar cells treated by backside polish, while curve D is measured using a sample not treated by backside polish, for example, using conventional RENA tool to perform the isolation.

More specifically, the curve A in FIG. 8 is measured by using the present invention solar cell that is fabricated by the steps as set forth through FIG. 3 to FIG. 7. The curve B is measured by using a solar cell that is fabricated using an RENA tool for isolation after the diffusion process, wherein the etch time period is extended to perform the backside polish. The curve C is measured by using a solar cell that is fabricated using a Schmid tool for isolation after the diffusion process, wherein the etch time period is extended to perform the backside polish.

It can be seen from the measurement of the backside reflectivity of the solar cells, compared to the comparative examples corresponding to curve B to curve D, the present invention solar cell has a high-reflectivity region that is able to achieve a higher reflectivity. It can be seen from FIG. 8 that the high-reflectivity region 20 of the present invention solar cell 1 has a reflectivity between 30˜70% with respect to light wavelength between 350˜450 nm, a reflectivity between 25˜50% with respect to light wavelength between 45˜1050 nm, for example, especially, a reflectivity of about 33% with respect to light wavelength of 600 nm, and a reflectivity between 30˜70% with respect to light wavelength between 1050˜1200 nm.

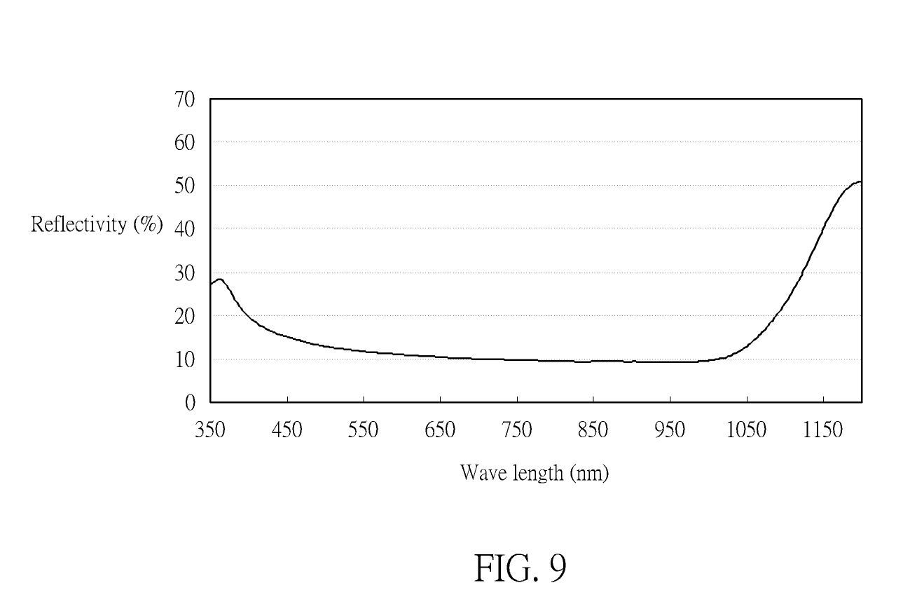

Please refer to FIG. 9. FIG. 9 shows a curve diagram of reflectivity of the low-reflectivity region versus light wavelength. The curve in FIG. 9 is measured according to the low-reflectivity region 10 on the front side of the solar cell. It can be seen from FIG. 9 that the low-reflectivity region 10 of the present invention solar cell 1 has a reflectivity between 10˜30% with respect to light wavelength between 350˜450 nm, a reflectivity between 5˜20% with respect to light wavelength between 450˜1050 nm, and a reflectivity between 10˜60% with respect to light wavelength between 1050˜1200 nm. When the high-reflectivity region 20 and the low-reflectivity region 10 are irradiated with light of the same wavelength, the reflectivity of the high-reflectivity region 20 is greater than that of the low-reflectivity region 10.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar cell, comprising:
a semiconductor substrate having a first surface and a second surface, the first surface comprises a low-reflectivity region and the second surface comprises a high-reflectivity region; and
an etch mark formed along perimeter of the first surface and surrounding the low-reflectivity region to thereby constitute an annular pattern, wherein the etch mark has an average width that is not greater than 2 mm, wherein when the high-reflectivity region and the low-reflectivity region are irradiated with light of the same wavelength, a reflectivity of the high-reflectivity region is greater than that of the low-reflectivity region.

2. The solar cell according to claim 1, wherein the high-reflectivity region has a reflectivity between 30˜70% with respect to light wavelength between 350˜450 nm.

3. The solar cell according to claim 1, wherein the high-reflectivity region has a reflectivity between 25˜50% with respect to light wavelength between 450˜1050 nm.

4. The solar cell according to claim 3, wherein the high-reflectivity region has a reflectivity of 33% with respect to light wavelength of 600 nm.

5. The solar cell according to claim 1, wherein the high-reflectivity region has a reflectivity between 30˜70% with respect to light wavelength between 1050˜1200 nm.

6. The solar cell according to claim 1, wherein the low-reflectivity region has a reflectivity between 10˜30% with respect to light wavelength between 350˜450 nm.

7. The solar cell according to claim 1, wherein the low-reflectivity region has a reflectivity between 5˜20% with respect to light wavelength between 450˜1050 nm.

8. The solar cell according to claim 1, wherein the low-reflectivity region has a reflectivity between 10˜60% with respect to light wavelength between 1050˜1200 nm.

9. The solar cell according to claim 1 further comprising a doped emitter layer and at least one anti-reflection layer on the first surface.

10. The solar cell according to claim 9, wherein the anti-reflection layer comprises silicon nitride, silicon oxide or silicon oxynitride.

11. The solar cell according to claim 1 further comprising a front side contact electrode on the first surface.

12. The solar cell according to claim 1 further comprising a back surface field and a backside contact electrode on the second surface.

13. The solar cell according to claim 1, wherein the semiconductor substrate comprises a crystalline silicon substrate.

14. A method for fabricating a solar cell, comprising:
providing a semiconductor substrate having a first surface and a second surface, wherein the first surface comprises a low-reflectivity region;
performing a wafer surface cleaning and texturing process to form textured surface structures on the first surface and the second surface;
performing a backside polish process to polish the textured surface structure on the second surface, thereby forming a high-reflectivity region on the second surface;
after the backside polish process, performing a diffusion process to form a phosphosilicate glass layer and a doped layer on the semiconductor substrate; and
performing an isolation process to remove the doped layer from the second surface and an edge of the semiconductor substrate, thereby forming an etch mark along perimeter of the first surface and surrounding the low-reflectivity region as an annular pattern.

15. The method according to claim 14, wherein the backside polish process comprises using a hydrophilic etchant to polish the second surface.

16. The method according to claim 15, wherein the hydrophilic etchant comprises hydrofluoric acid (HF), nitric acid (HNO₃), and sulfuric acid (H₂SO₄).

17. The method according to claim 15, wherein in the backside polish process, the semiconductor substrate is horizontally placed on a plurality of rollers, and driven by the rollers, the hydrophilic etchant contacts the second surface for a predetermined time period, whereby a predetermined thickness of the second surface is etched away.

18. The method according to claim 17, wherein the predetermined time period ranges between 80 seconds and 360 seconds, and the predetermined thickness ranges between 1.3 micrometers and 6 micrometers.

19. The method according to claim 14, wherein the etch mark has an average width that is not greater than 2 mm.

20. The method according to claim 14 further comprising:
forming at least an anti-reflection layer on the doped layer on the first surface;
screen printing electrode patterns on the first surface and the second surface by using metal slurry; and
sintering at high temperatures to form contact electrodes.
